(19) United States
(12) Patent Application Publication
(10) Pub. No.: US 2021/0066077 A1
(43) Pub. Date: Mar. 4, 2021

(54) APPARATUS AND METHOD FOR TREATING SUBSTRATE

(71) Applicant: SEMES CO., LTD., Cheonan-si (KR)

(72) Inventors: Byungsun Bang, Hwaseong-si (KR); Youngil Lee, Cheonan-si (KR)

(73) Assignee: SEMES CO., LTD., Cheonan-si (KR)

(21) Appl. No.: 17/004,079

(22) Filed: Aug. 27, 2020

(30) Foreign Application Priority Data
Aug. 27, 2019 (KR) 10-2019-0104865

(51) Int. Cl. H01L 21/02; H01L 21/67

(52) U.S. Cl. CPC H01L 21/02343; H01L 21/67248; H01L 21/67075; H01L 21/0217

(57) ABSTRACT

The inventive concept relates to a method for treating a substrate. In an embodiment, a method for etching a substrate having a silicon nitride layer includes etching the silicon nitride layer by dispensing a first treatment liquid having a set temperature and a set concentration onto the substrate heated to a set temperature, in which a second treatment liquid is additionally dispensed for a set period of time in an overlapping manner while the first treatment liquid is dispensed in the silicon nitride layer etching process.

### CROSS-REFERENCE TO RELATED APPLICATIONS

A claim for priority under 35 U.S.C. § 119 is made to Korean Patent Application No. 10-2019-0104865 filed on Aug. 27, 2019, in the Korean Intellectual Property Office, the entire contents of which are hereby incorporated by reference.

### BACKGROUND

Embodiments of the inventive concept described herein relate to an apparatus and method for treating a substrate.

Various processes, such as photolithography, etching, ashing, ion implantation, thin-film deposition, cleaning, and the like, are performed on a substrate to manufacture semiconductor elements or a liquid crystal display. Among these processes, the etching process is a process of removing unnecessary regions from a thin film formed on the substrate, and a high selectivity and a high etching rate are required for the thin film.

In general, in an etching or cleaning process, a chemical processing step, a rinsing step, and a drying step are sequentially performed on a substrate. In the chemical processing step, a chemical is dispensed onto the substrate to etch a thin film formed on the substrate or remove foreign matter on the substrate. The chemical is dispensed in a state of being heated to a high temperature, and a heater provided in a support unit heats the substrate.

### SUMMARY

Embodiments of the inventive concept provide a substrate treating apparatus and method for efficiently treating a substrate.

In addition, embodiments of the inventive concept provide a substrate treating apparatus and method for improving temperature uniformity.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, a method for etching a substrate having a silicon nitride layer includes etching the silicon nitride layer by dispensing a first treatment liquid having a set temperature and a set concentration onto the substrate heated to a set temperature, in which a second treatment liquid is additionally dispensed for a set period of time in an overlapping manner while the first treatment liquid is dispensed in the silicon nitride layer etching process.

In an embodiment, the first treatment liquid may be a first phosphoric acid solution, and the second treatment liquid may be a second phosphoric acid solution. The first phosphoric acid solution may differ from the second phosphoric acid solution in terms of at least one of a set temperature and a set concentration.

In an embodiment, the first phosphoric acid solution may be a phosphoric acid solution or a mixture of a phosphoric acid solution and a silicon-based chemical, and the second phosphoric acid solution may be a phosphoric acid solution or a mixture of a phosphoric acid solution and a silicon-based chemical.

In an embodiment, a third treatment liquid having a set temperature and a set concentration may be additionally dispensed onto the substrate.

In an embodiment, the third treatment liquid may be a silicon-mixed solution.

In an embodiment, the silicon-mixed solution may be at least one of a phosphoric acid solution or DIW.

In an embodiment, the concentration of silicon (Si) contained in the third treatment liquid may be higher than the concentration of silicon (Si) contained in the first treatment liquid and the second treatment liquid.

In an embodiment, at least one of a dispensing position, dispensing time, and a dispensing flow rate of at least one of the first treatment liquid and the second treatment liquid may be adjusted based on a temperature measurement result of a temperature sensor that measures temperatures of respective regions of the substrate.

In an embodiment, the method may include a step of loading a first substrate, a step of collecting a surface temperature measurement result of the first substrate while treating the first substrate by dispensing the first phosphoric acid solution onto the first substrate, and a step of setting at least one of a dispensing position, dispensing time, and a dispensing flow rate of the second treatment liquid, based on the collected surface temperature measurement result.

In an embodiment, the dispensing position of the second treatment liquid may correspond to a region, the temperature of which is measured to be high in a process of treating the first substrate.

In an embodiment, the dispensing time of the second treatment liquid may range from any time point when temperature starts to rise in a process of treating the first substrate to any time point before the temperature falls.

In an embodiment, the first substrate may be treated by additionally dispensing the third treatment liquid.

In an embodiment, the first treatment liquid may be dispensed at a temperature of 130 degrees Celsius to 200 degrees Celsius.

In an embodiment, the second treatment liquid may be dispensed at a temperature of 130 degrees Celsius to 200 degrees Celsius.

In an embodiment, the silicon-mixed solution may be dispensed at a temperature of 10 degrees Celsius to 175 degrees Celsius.

In an embodiment, the first treatment liquid may be dispensed at a flow rate of 0 cc/min to 1000 cc/min.

In an embodiment, the second treatment liquid may be dispensed at a flow rate of 0 cc/min to 1000 ccc/min.

In an embodiment, a state in which the second treatment liquid is dispensed for a set period of time and a state in which the second treatment liquid is not dispensed for the set period of time may be repeated.

In an embodiment, the third treatment liquid may be dispensed at a flow rate of 0 cc/min to 100 cc/min.

In an embodiment, at least one of the first treatment liquid, the second treatment liquid, and the third treatment liquid may be dispensed while moving above a set region of the substrate.

In an embodiment, the second treatment liquid may be fixedly dispensed onto a set region of the substrate in a process of treating the substrate.

In an embodiment, the second treatment liquid may be dispensed while moving above a set region of the substrate in a process of treating the substrate.

According to an exemplary embodiment, an apparatus for treating a substrate includes a support unit that supports the substrate and that is provided so as to be rotatable, a heater that heats the substrate, a first nozzle that dispenses a first treatment liquid onto the substrate in a substrate treating process, the first treatment liquid being one of a phosphoric acid solution or a mixture of a phosphoric acid solution and a silicon-based chemical, and a second nozzle that dispenses a second treatment liquid onto the substrate in the substrate treating process, the second treatment liquid being one of a phosphoric acid solution or a mixture of a phosphoric acid solution and a silicon-based chemical.

In an embodiment, the apparatus may further include a controller and a temperature sensor that measures temperatures of respective regions of the substrate, and the controller may control at least one of a dispensing position, dispensing time, and a dispensing flow rate of at least one of the first nozzle and the second nozzle, based on a temperature measurement result of the temperature sensor.

In an embodiment, a dispensing position of the second treatment liquid may correspond to a region, the temperature of which is measured to be high in a process of treating a first substrate.

In an embodiment, dispensing time of the second treatment liquid may range from any time point when temperature starts to rise in a process of treating a first substrate to any time point before the temperature falls.

In an embodiment, a state in which the second treatment liquid is dispensed for a set period of time and a state in which the second treatment liquid is not dispensed for the set period of time may be repeated.

In an embodiment, the second nozzle may dispense the second treatment liquid in a spray form.

In an embodiment, the apparatus may further include a third nozzle that dispenses a third treatment liquid onto the substrate in the substrate treating process, the third treatment liquid being a silicon-based chemical.

In an embodiment, the third treatment liquid may additionally contain one of a phosphoric acid solution or DIW, in addition to the silicon-based chemical. The concentration of silicon (Si) contained in the third treatment liquid may be higher than the concentration of silicon (Si) contained in the first treatment liquid and the second treatment liquid.

In an embodiment, the first treatment liquid may be dispensed at a temperature of 130 degrees Celsius to 200 degrees Celsius, the second treatment liquid may be dispensed at a temperature of 130 degrees Celsius to 200 degrees Celsius, and the third treatment liquid may be dispensed at a temperature of 10 degrees Celsius to 175 degrees Celsius.

In an embodiment, the first treatment liquid may be dispensed at a flow rate of 0 cc/min to 1000 ccc/min, the second treatment liquid may be dispensed at a flow rate of 0 cc/min to 1000 ccc/min, and the third treatment liquid may be dispensed at a flow rate of 0 cc/min to 100 ccc/min.

In an embodiment, at least one of the first nozzle, the second nozzle, and the third nozzle may dispense a liquid while moving above a set region of the substrate.

In an embodiment, the second nozzle may be fixed to dispense the second treatment liquid onto a set region of the substrate in the substrate treating process.

In an embodiment, the third nozzle may dispense the third treatment liquid while moving above a set region of the substrate in the substrate treating process.

In an embodiment, the heater may include a heating member that heats the substrate by region.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view illustrating a substrate treating apparatus according to an embodiment of the inventive concept;

FIG. 2 is a view illustrating a process chamber according to an embodiment;

FIG. 3 is a view illustrating nozzles according to an embodiment and flow lines according to an embodiment;

FIG. 4 is a view illustrating nozzles according to another embodiment and the flow lines according to the embodiment;

FIG. 5 is a view illustrating the nozzles according to the embodiment and flow lines according to another embodiment;

FIG. 6 is a view illustrating the nozzles according to the embodiment and flow lines according to another embodiment;

FIG. 7 is a top view illustrating operations of the nozzles according to the embodiment;

FIG. 8 is a view illustrating substrate temperature distribution at one time point when a first substrate is treated according to an embodiment;

FIG. 9 is a view illustrating temperature changes at respective points of the first substrate over time when the first substrate is treated according to an embodiment; and

FIG. 10 is a flowchart illustrating a substrate treating method according to an embodiment.

### DETAILED DESCRIPTION

Various modifications and variations can be made to embodiments of the inventive concept, and the scope of the inventive concept should not be construed as limited to the embodiments set forth herein. These embodiments are provided so that the inventive concept will be thorough and complete, and will fully convey the scope of the inventive concept to those skilled in the art. Accordingly, in the drawings, the shapes of components are exaggerated for clarity of illustration.

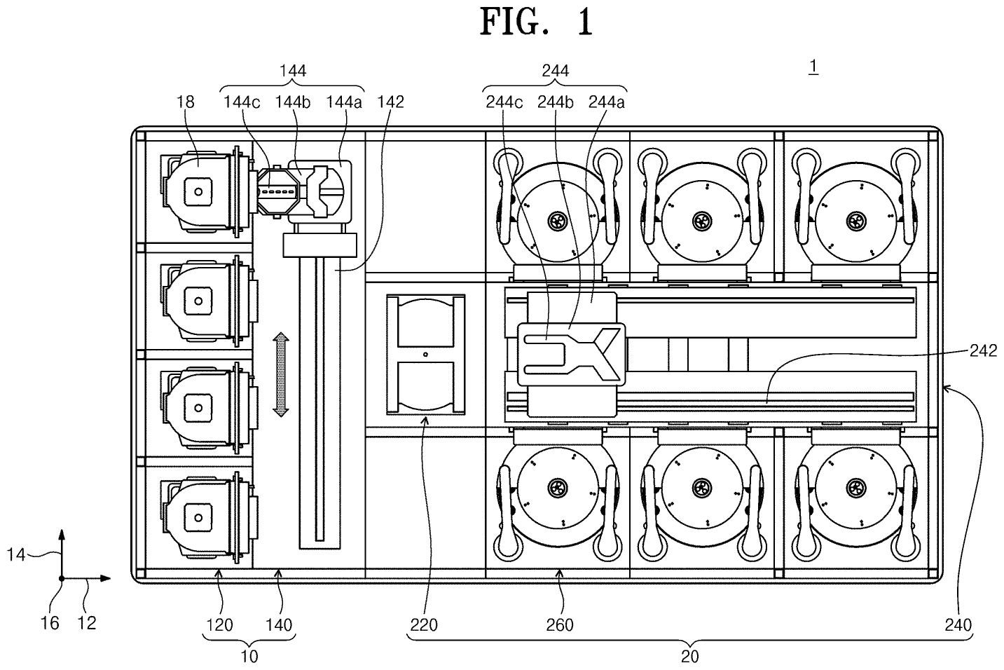

FIG. 1 is a plan view illustrating a substrate treating apparatus according to an embodiment of the inventive concept.

Referring to FIG. 1, the substrate treating apparatus 1 includes an index module 10 and a process module 20.

The index module 10 includes load ports 120 and a transfer frame 140. The load ports 120, the transfer frame 140, and the process module 20 are sequentially arranged in a row. Hereinafter, a direction in which the load ports 120, the transfer frame 140, and the process module 20 are arranged is referred to as a first direction 12, a direction perpendicular to the first direction 12 when viewed from above is referred to as a second direction 14, and a direction perpendicular to the plane including the first direction 12 and the second direction 14 is referred to as a third direction 16.

Carriers 18, each of which has substrates W received therein, are located on the load ports 120. The load ports 120 are disposed in a row along the second direction 14. The number of load ports 120 may be increased or decreased depending on conditions such as process efficiency and footprint of the process module 20. Each of the carriers 18 has a plurality of slots (not illustrated) formed therein in which the substrates W are received in a horizontal position relative to the ground. Front opening unified pods (FOUPs) may be used as the carriers 18.

The process module 20 has a buffer unit 220, a transfer chamber 240, and process chambers 260. The transfer chamber 240 is disposed such that the lengthwise direction thereof is parallel to the first direction 12. The process chambers 260 are disposed on opposite sides of the transfer chamber 240. On the opposite sides of the transfer chamber 240, the process chambers 260 are provided to be symmetric to each other with respect to the transfer chamber 240. The process chambers 260 are provided on one side of the transfer chamber 240. Some of the process chambers 260 are disposed along the lengthwise direction of the transfer chamber 240. Furthermore, other process chambers 260 are stacked one above another. That is, the process chambers 260 may be disposed in an A×B array on the one side of the transfer chamber 240. Here, “A” denotes the number of process chambers 260 provided in a row along the first direction 12, and “B” denotes the number of process chambers 260 provided in a column along the third direction 16.

In a case where four or six process chambers 260 are provided on the one side of the transfer chamber 240, the process chambers 260 may be disposed in a 2×2 or 3×2 array. The number of process chambers 260 may be changed. Alternatively, the process chambers 260 may be provided on only the one side of the transfer chamber 240. In another case, the process chambers 260 may be provided in a single layer on the opposite sides of the transfer chamber 240.

The buffer unit 220 is disposed between the transfer frame 140 and the transfer chamber 240. The buffer unit 220 provides a space in which the substrates W stay before transferred between the transfer chamber 240 and the transfer frame 140. The buffer unit 220 has slots (not illustrated) formed therein in which the substrates W are placed. The slots (not illustrated) are spaced apart from each other along the third direction 16. The buffer unit 220 is open at one side facing the transfer frame 140 and at an opposite side facing the transfer chamber 240.

The transfer frame 140 transfers the substrates W between the carriers 18 seated on the load ports 120 and the buffer unit 220. An index rail 142 and an index robot 144 are provided in the transfer frame 140. The index rail 142 is disposed such that the lengthwise direction thereof is parallel to the second direction 14. The index robot 144 is installed on the index rail 142 and linearly moves along the index rail 142 in the second direction 14. The index robot 144 has a base 144a, a body 144b, and index arms 144c. The base 144a is installed so as to be movable along the index rail 142. The body 144b is coupled to the base 144a. The body 144b is movable on the base 144a along the third direction 16. Furthermore, the body 144b is rotatable on the base 144a. The index arms 144c are coupled to the body 144b and are movable forward and backward relative to the body 144b. The index arms 144c may be individually operated. The index arms 144c are stacked one above another with a spacing gap therebetween along the third direction 16. Some of the index arms 144c may be used to transfer the substrates W from the process module 20 to the carriers 18, and the other index arms 144c may be used to transfer the substrates W from the carriers 18 to the process module 20. Accordingly, particles generated from the substrates W that are to be treated may be prevented from adhering to the treated substrates W in the process in which the index robot 144 transfers the substrates W between the carriers 18 and the process module 20.

The transfer chamber 240 transfers the substrates W between the buffer unit 220 and the process chambers 260 and between the process chambers 260. A guide rail 242 and a main robot 244 are provided in the transfer chamber 240. The guide rail 242 is disposed such that the lengthwise direction thereof is parallel to the first direction 12. The main robot 244 is installed on the guide rail 242 and linearly moves on the guide rail 242 along the first direction 12. The main robot 244 has a base 244a, a body 244b, and main arms 244c. The base 244a is installed so as to be movable along the guide rail 242. The body 244b is coupled to the base 244a. The body 244b is movable on the base 244a along the third direction 16. Furthermore, the body 244b is rotatable on the base 244a. The main arms 244c are coupled to the body 244b and are movable forward and backward relative to the body 244b. The main arms 244c may be individually operated. The main arms 244c are stacked one above another with a spacing gap therebetween along the third direction 16.

The process chambers 260 perform cleaning processes on the substrates W. The process chambers 260 may have different structures depending on the types of cleaning processes performed. Alternatively, the process chambers 260 may have the same structure. Selectively, the process chambers 260 may be divided into a plurality of groups. The process chambers 260 belonging to the same group may have the same structure, and the process chambers 260 belonging to different groups may have different structures.

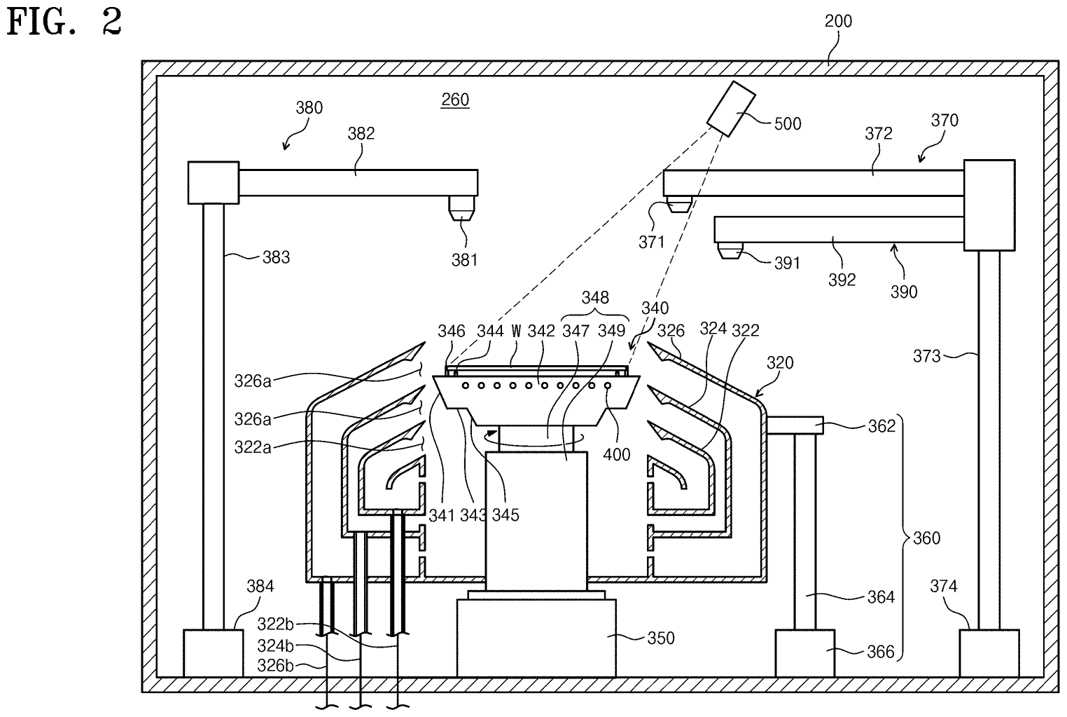

FIG. 2 is a view illustrating one embodiment of the process chambers.

Referring to FIG. 2, the process chamber 260 includes a cup 320, a substrate support unit 340, a lifting unit 360, a first treatment liquid dispensing unit 370, a second treatment liquid dispensing unit 390, a third treatment liquid dispensing unit 380, and a controller (not illustrated).

As will be described below, the controller (not illustrated) controls the components of the process chamber 260 to treat a substrate W depending on a set process.

The cup 320 has a process space in which the substrate W is treated. The cup 320 has a cylindrical shape with an open top. The cup 320 has an inner recovery bowl 322, an intermediate recovery bowl 324, and an outer recovery bowl 326. The inner recovery bowl 322, the intermediate recovery bowl 324, and the outer recovery bowl 326 recover different treatment liquids used for the process. The inner recovery bowl 322 has an annular ring shape that surrounds the substrate support unit 340. The intermediate recovery bowl 324 has a ring shape that surrounds the inner recovery bowl 322. The outer recovery bowl 326 has a ring shape that surrounds the intermediate recovery bowl 324. An interior space 322a of the inner recovery bowl 322, a space 326a between the inner recovery bowl 322 and the intermediate recovery bowl 324, and a space 326a between the intermediate recovery bowl 324 and the outer recovery bowl 326 function as inlets through which the treatment liquids are introduced into the inner recovery bowl 322, the intermediate recovery bowl 324, and the outer recovery bowl 326.

According to an embodiment, the inlets may be located at different heights. A first recovery line 322b, a second recovery line 324b, and a third recovery line 326b are connected to the bottoms of the inner recovery bowl 322, the intermediate recovery bowl 324, and the outer recovery bowl 326. The treatment liquids introduced into the inner recovery bowl 322, the intermediate recovery bowl 324, and the outer recovery bowl 326 may be provided to an external treatment liquid regeneration system (not illustrated) through the first recovery line 322b, the second recovery line 324b, and the third recovery line 326b and may be reused.

The substrate support unit 340 supports and rotates the substrate W during the process. The substrate support unit 340 includes a spin chuck 342, support pins 344, chuck pins 346, and a support shaft 348. The spin chuck 342 has an upper surface in a substantially circular shape when viewed from above. An outside surface of the spin chuck 342 has a step. A bottom surface of the spin chuck 342 has a smaller diameter than the upper surface of the spin chuck 342. The outside surface of the spin chuck 342 has a first inclined surface 341, a horizontal surface 343, and a second inclined surface 345. The first inclined surface 341 extends downward from the upper surface of the spin chuck 342. The horizontal surface 343 extends inward from a lower end of the first inclined surface 341. The second inclined surface 345 extends downward from an inside end of the horizontal surface 343. The first inclined surface 341 and the second inclined surface 345 are downwardly inclined toward the central axis of the spin chuck 342.

The support pins 344 are disposed on an edge portion of the upper surface of the spin chuck 342 so as to be spaced apart from each other at predetermined intervals. The support pins 344 protrude upward from the spin chuck 342. The support pins 344 are arranged to form a ring shape as a whole by a combination thereof. The support pins 344 support an edge portion of a rear surface of the substrate W such that the substrate W is spaced apart from the upper surface of the spin chuck 342 by a predetermined distance.

The chuck pins 346 are disposed farther away from the central axis of the spin chuck 342 than the support pins 344. The chuck pins 346 protrude upward from the spin chuck 342. The chuck pins 346 support the side of the substrate W to prevent the substrate W from deviating from a correct position to a side when the substrate support unit 340 rotates. The chuck pins 346 are linearly movable between a standby position and a support position along the radial direction of the spin chuck 342. The standby position is farther away from the center of the spin chuck 342 than the support position. The chuck pins 346 are located in the standby position when the substrate W is loaded onto or unloaded from the substrate support unit 340. The chuck pins 346 are located in the support position when the process is performed on the substrate W. In the support position, the chuck pins 346 are brought into contact with the side of the substrate W.

The support shaft 348 rotatably supports the spin chuck 342. The support shaft 348 is located under the spin chuck 342. The support shaft 348 includes a rotary shaft 347 and a fixed shaft 349. The rotary shaft 347 is provided as an inner shaft, and the fixed shaft 349 is provided as an outer shaft. The rotary shaft 347 is provided such that the lengthwise direction thereof is parallel to the third direction 16. The rotary shaft 347 is fixedly coupled to the bottom surface of the spin chuck 342. The rotary shaft 347 is rotatable by a drive member 350. The spin chuck 342 rotates together with the rotary shaft 347. The fixed shaft 349 has a hollow cylindrical shape that surrounds the rotary shaft 347. The fixed shaft 349 has a larger diameter than the rotary shaft 347. An inner surface of the fixed shaft 349 is spaced apart from the rotary shaft 347. The fixed shaft 340 remains in a fixed state while the rotary shaft 347 is rotated.

Heating members 400 are located inside the spin chuck 342 and heat the substrate W. The heating members 400 may heat the entire area of the substrate W. According to an embodiment, the heating members 400 may heat the substrate W by region. According to an embodiment, the heating members 400 may have a coil shape and may be provided inside the spin chuck 342 at uniform intervals. When the heating members 400 heat the spin chuck 342, the substrate W is dried while heat is conducted to the rear surface of the substrate W that is brought into contact with the spin chuck 342. According to another embodiment, the substrate W may be rotated while being heated. Alternatively, the heating members 400 may be implemented with lamps (not illustrated) and may be located over the substrate W. In this case, the lamps may heat an upper surface of the substrate W to dry the substrate W.

The lifting unit 360 moves the cup 320 in the vertical direction. As the cup 320 is vertically moved, the height of the cup 320 relative to the substrate support unit 340 is changed. The lifting unit 360 has a bracket 362, a movable shaft 364, and an actuator 366.

The bracket 362 is attached to an outer wall of the cup 320, and the movable shaft 364 is coupled to the bracket 362 and is vertically moved by the actuator 366. When the substrate W is placed on the substrate support unit 340 or lifted upward from the substrate support unit 340, the cup 320 is moved downward such that the substrate support unit 340 protrudes above the cup 320. Furthermore, when the process is performed, the height of the cup 320 is adjusted depending on the types of treatment liquids dispensed onto the substrate W, such that the treatment liquids are introduced into the preset recovery bowls 322, 324, and 326. Selectively, the lifting unit 360 may vertically move the substrate support unit 340.

The first treatment liquid dispensing unit 370 dispenses a treatment liquid onto the substrate W. The first treatment liquid dispensing unit 370 may dispense, onto the substrate W, a first treatment liquid heated to a set temperature to improve efficiency in treating the substrate W. The first treatment liquid dispensing unit 370 includes a first support shaft 373, a first arm 372, and a first nozzle 371. The first support shaft 373 is disposed on one side of the cup 320. The first support shaft 373 has a rod shape, the lengthwise direction of which is oriented in the vertical direction. The first support shaft 373 is rotatable and movable upward and downward by a drive member 374. Alternatively, the first support shaft 373 may be linearly moved in the horizontal direction and moved upward and downward by the drive member 374. The first arm 372 supports the first nozzle 371. The first arm 372 is coupled to the first support shaft 373, and the first nozzle 371 is fixedly coupled to a bottom surface of a distal end of the first arm 372. The first nozzle 371 may be swung by rotation of the first support shaft 373 or the first arm 372. The first nozzle 371 may be movable between a process position and a standby position by rotation of the first support shaft 373 or movement of the first arm 372.

Here, the process position is a position in which the first nozzle 371 faces the substrate support unit 340, and the standby position is a position in which the first nozzle 371 deviates from the process position.

The first treatment liquid may be one of a phosphoric acid solution or a mixture of a phosphoric acid solution and a silicon-based chemical. The first treatment liquid may be a chemical, the concentration of which is adjusted by adding deionized water to a phosphoric acid solution. The first treatment liquid is dispensed at a temperature of 130 degrees Celsius to 200 degrees Celsius at a flow rate of 0 cc/min to 1000 cc/min.

The second treatment liquid dispensing unit 390 dispenses a treatment liquid onto the substrate W. The second treatment liquid dispensing unit 390 may dispense, onto the substrate W, a second treatment liquid heated to a set temperature to improve efficiency in treating the substrate W. The second treatment liquid dispensing unit 380 includes a second arm 392 and a second nozzle 391. The second arm 392 supports the second nozzle 391. The second arm 392 is coupled to the first support shaft 373, and the second nozzle 391 is fixedly coupled to a bottom surface of a distal end of the second arm 392. The second nozzle 391 may be swung by rotation of the second arm 392. The second nozzle 391 may be movable between a process position and a standby position by rotation of the second arm 392. Alternatively, the second arm 392 may be connected to a separate support shaft (not illustrated), and the second nozzle 391 may be movable between the process position and the standby position by swinging the separate support shaft (not illustrated).

Here, the process position is a position in which the second nozzle 391 faces the substrate support unit 340, and the standby position is a position in which the second nozzle 391 deviates from the process position.

The second treatment liquid may be one of a phosphoric acid solution or a mixture of a phosphoric acid solution and a silicon-based chemical. The second treatment liquid may be a chemical, the concentration of which is adjusted by adding deionized water to a phosphoric acid solution. The second treatment liquid is dispensed at a temperature of 130 degrees Celsius to 200 degrees Celsius at a flow rate of 0 cc/min to 1000 cc/min. A state in which the second treatment liquid is dispensed for a set period of time and a state in which the second treatment liquid is not dispensed for the set period of time may be repeated.

The third treatment liquid dispensing unit 380 dispenses a treatment liquid onto the substrate W. The third treatment liquid dispensing unit 380 may dispense, onto the substrate W, a third treatment liquid heated to a set temperature to improve efficiency in treating the substrate W. The third treatment liquid dispensing unit 380 includes a third support shaft 383, a third arm 382, and a third nozzle 381. The third support shaft 383 is disposed on one side of the cup 320. The third support shaft 383 has a rod shape, the lengthwise direction of which is oriented in the vertical direction. The third support shaft 383 is rotatable and movable upward and downward by a drive member 384. Alternatively, the third support shaft 383 may be linearly moved in the horizontal direction and moved upward and downward by the drive member 384. The third arm 382 supports the third nozzle 381. The third arm 382 is coupled to the third support shaft 383, and the third nozzle 381 is fixedly coupled to a bottom surface of a distal end of the third arm 382. The third nozzle 381 may be swung by rotation of the third support shaft 383. The third nozzle 381 may be movable between a process position and a standby position by rotation of the third support shaft 383.

Here, the process position is a position in which the third nozzle 381 faces the substrate support unit 340, and the standby position is a position in which the third nozzle 381 deviates from the process position.

The third treatment liquid is a silicon-based chemical. The third treatment liquid may further include at least one of a phosphoric acid solution or DIW, in addition to the silicon-based chemical. The phosphoric acid solution included may be a chemical, the concentration of which is adjusted by adding deionized water. The third treatment liquid is dispensed at a temperature of 10 degrees Celsius to 175 degrees Celsius at a flow rate of 0 cc/min to 100 cc/min.

The concentration of silicon (Si) contained in the third treatment liquid is higher than the concentration of silicon (Si) contained in the first treatment liquid and the second treatment liquid.

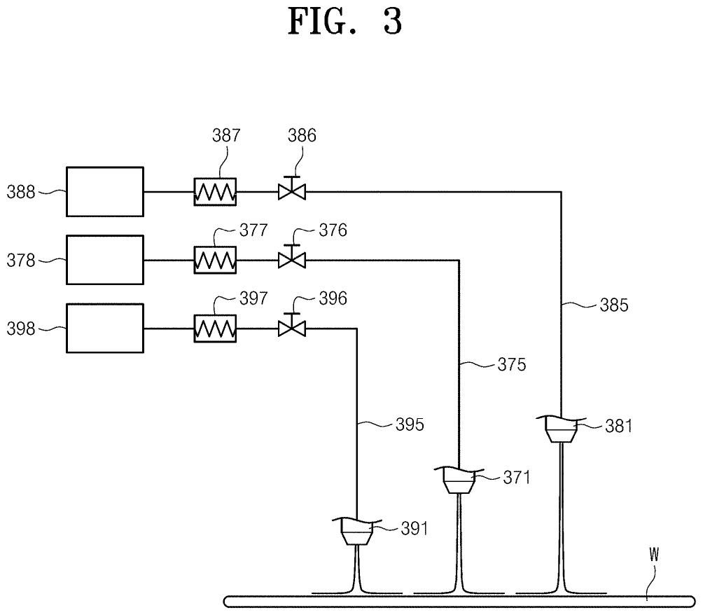

FIG. 3 is a view illustrating nozzles according to an embodiment and flow lines according to an embodiment. Referring to FIG. 3, the first nozzle 371 is connected to a first supply line 375, and the first supply line 375 is connected to a first supply source 378. The first supply source 378 stores the first treatment liquid. The second nozzle 391 is connected to a second supply line 395, and the second supply line 395 is connected to a second supply source 398. The second supply source 398 stores the second treatment liquid. The third nozzle 381 is connected to a third supply line 385, and the third supply line 385 is connected to a third supply source 388. The third supply source 378 stores the third treatment liquid.

A first heater 377 and a first flow rate adjustment member 376 are provided on the first supply line 375. A second heater 397 and a second flow rate adjustment member 396 are provided on the second supply line 395. A third heater 387 and a third flow rate adjustment member 386 are provided on the third supply line 385.

The first nozzle 371, the second nozzle 391, and the third nozzle 381 dispense the treatment liquids in the form of a flow.

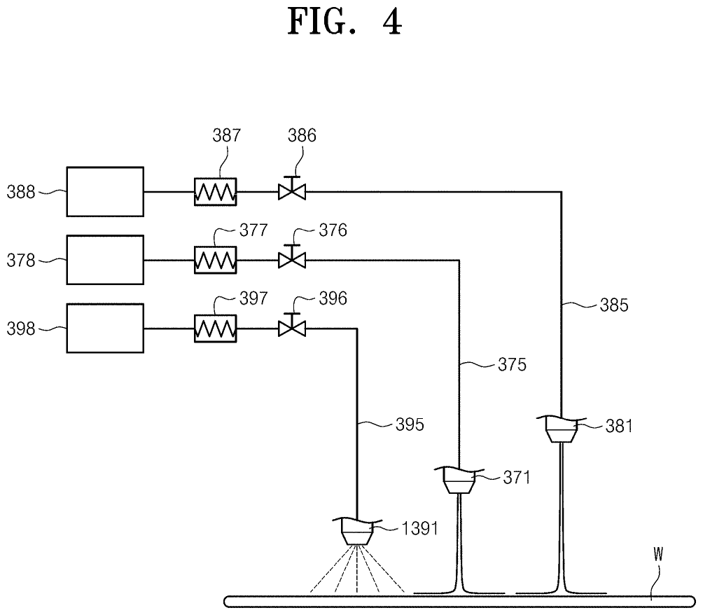

FIG. 4 is a view illustrating nozzles according to another embodiment and the flow lines according to the embodiment. Referring to FIG. 4, a second nozzle 1391 may dispense the second treatment liquid in a spray form.

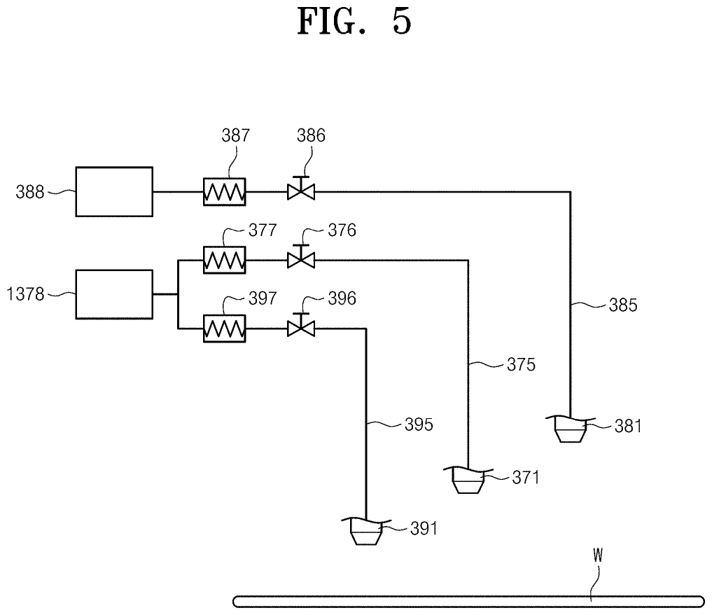

FIG. 5 is a view illustrating the nozzles according to the embodiment and flow lines according to another embodiment. Referring to FIG. 5, the first supply line 375 and the second supply line 395 are connected at a front end of a supply source. That is, a supply line connected to a first supply source 1378 is split into the first supply line 375 and the second supply line 395. The first heater 377 and the first flow rate adjustment member 376 are provided on the first supply line 375. The second heater 397 and the second flow rate adjustment member 396 are provided on the second supply line 395. The temperature of the first treatment liquid dispensed from the first nozzle 371 may differ from the temperature of the second treatment liquid dispensed from the second nozzle 391.

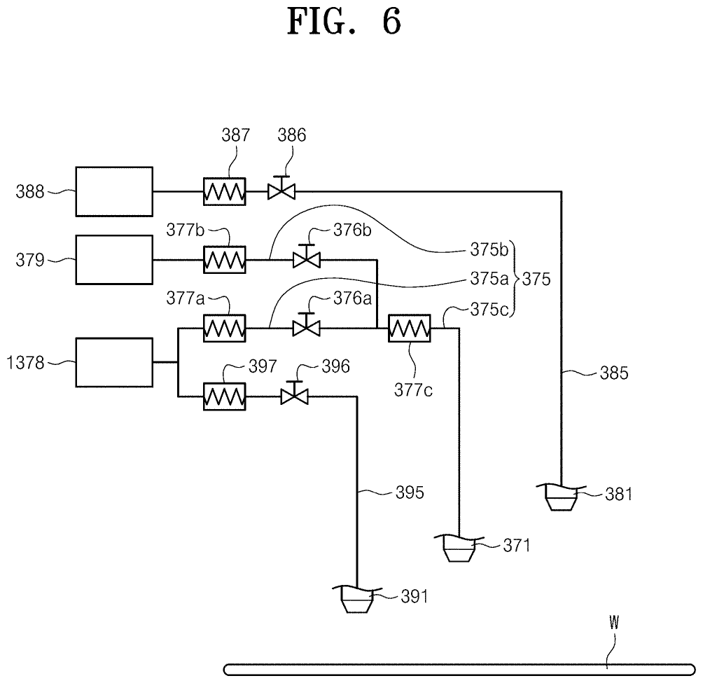

FIG. 6 is a view illustrating the nozzles according to the embodiment and flow lines according to another embodiment. Referring to FIG. 6, a first supply line 375a and the second supply line 395 are connected at a front end of a supply source. That is, a supply line connected to the first supply source 1378 is split into the first supply line 375a and the second supply line 395. The first supply line 375a is connected with an auxiliary line 375b at one point. The auxiliary line 575b is connected with an auxiliary liquid supply source 379. The auxiliary liquid supply source 379 may store an auxiliary liquid for adjusting the concentration of the first treatment liquid. According to an embodiment, the auxiliary liquid may be one of DIW, a phosphoric acid solution, and a silicon-mixed solution, or a combination thereof. A first heater 377a and a first flow rate adjustment member 376a are provided on the first supply line 375a. A fourth heater 377b and a fourth flow rate adjustment member 376b are provided on the auxiliary line 375b. The second heater 397 and the second flow rate adjustment member 396 are provided on the second supply line 395. A fifth heater 377c may be provided on an integrated line 375c to which the first supply line 375a and the auxiliary line 375 are connected. The temperature of the first treatment liquid dispensed from the first nozzle 371 may differ from the temperature of the second treatment liquid dispensed from the second nozzle 391.

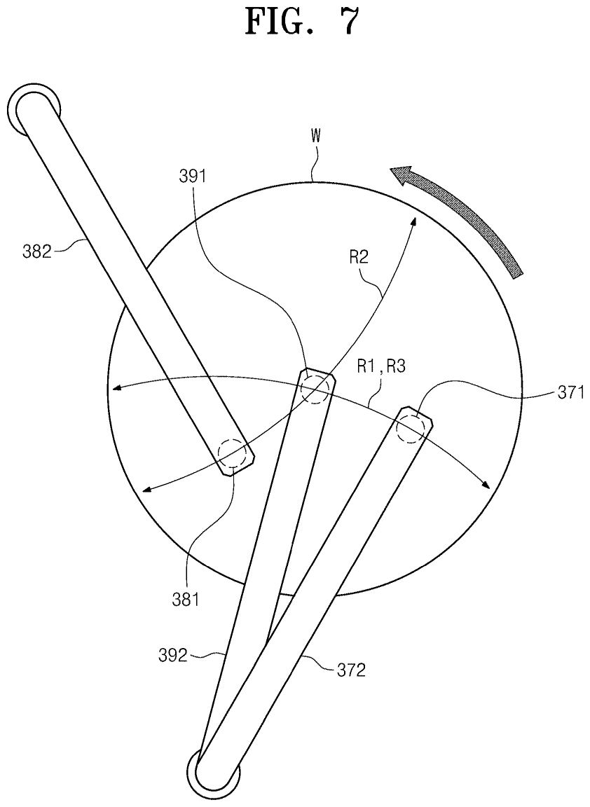

FIG. 7 is a top view illustrating operations of the nozzles according to the embodiment. Referring to FIG. 7, the first nozzle 371 may scan the substrate W along a path R1. The second nozzle 391 may scan the substrate W along a path R2.

The third nozzle 381 may scan the substrate W along a path R3. According to an embodiment, the first nozzle 371 dispenses the first treatment liquid onto the substrate W while moving above a set region of the substrate W. The set region may be a region from the center of the substrate W to the edge of the substrate W. Alternatively, the set region may be a region from an end portion of a central region of the substrate W to the edge of the substrate W. According to an embodiment, the third nozzle 381 dispenses the third treatment liquid onto the substrate W while moving above a set region of the substrate W. The set region may be a region from the center of the substrate W to the edge of the substrate W. Alternatively, the set region may be a region from an end portion of a central region of the substrate W to the edge of the substrate W.

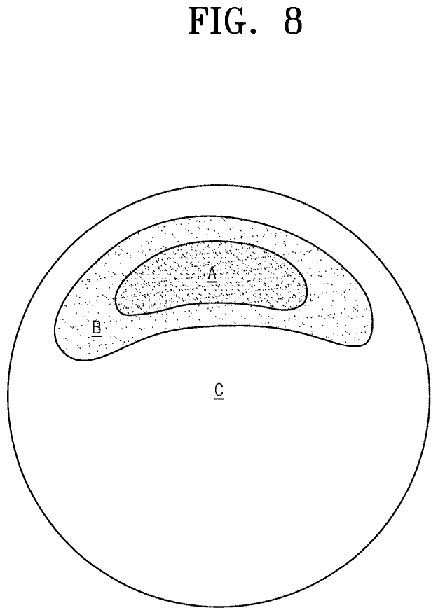

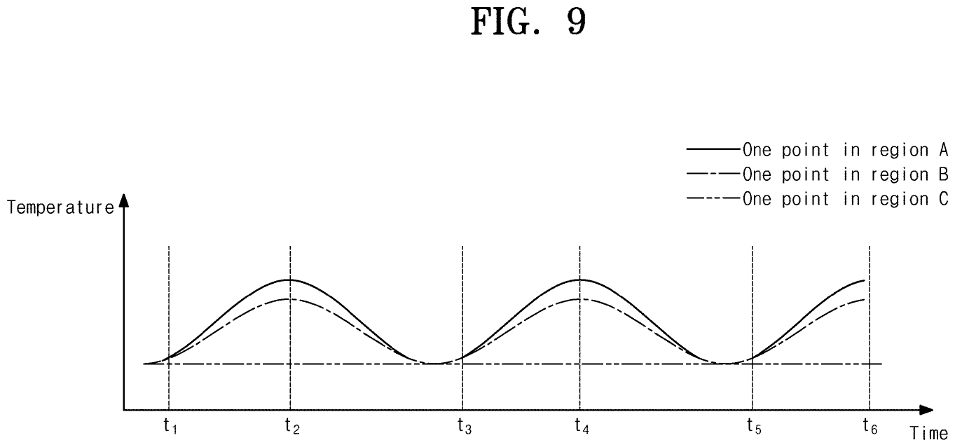

FIG. 8 is a view illustrating substrate temperature distribution at one time point when a first substrate is treated according to an embodiment, and FIG. 9 is a view illustrating temperature changes at respective points of the first substrate over time when the first substrate is treated according to an embodiment. Referring to FIGS. 8 and 9, in a substrate treating process, region A of a substrate may be raised to a higher temperature than region B and region C of the substrate for a predetermined period of time.

The substrate is heated by a heater while being treated. The temperatures of the first treatment liquid, the second treatment liquid, and the third treatment liquid dispensed are lower than the temperature to which the substrate is heated. Therefore, when at least one of the first treatment liquid, the second treatment liquid, and the third treatment liquid is dispensed onto the substrate, the surface temperature of the substrate is lowered, and while the first treatment liquid, the second treatment liquid, and the third treatment liquid are not dispensed onto the substrate, the surface temperature of the substrate is raised.

According to an embodiment of the inventive concept, a temperature sensor 500 measures a change in the surface temperature of the substrate for each time and region. According to an embodiment, in a case of treating the first substrate, which is a test substrate, with the first treatment liquid and the third treatment liquid, as illustrated in FIG. 9, the temperature change at one point in region A is large, the temperature change at one point in region B is smaller than the temperature change at the one point in region A, but is relatively large, and the temperature at one point in region C remains constant with little change.

At least one of a dispensing position, dispensing time, and a dispensing flow rate of at least one of the first treatment liquid, the second treatment liquid, and the third treatment liquid may be adjusted based on a substrate surface temperature measurement result of the temperature sensor 500. According to an embodiment, at least one of a dispensing position, dispensing time, and a dispensing flow rate of the second treatment liquid is set based on a result obtained by collecting the surface temperature of the substrate. The temperature at the one point in region A rises in a time interval from t1 to t2, a time interval from t3 to t4, and a time interval from t5 to t6 in FIG. 9. The temperature at the one point in region A falls in a time interval from t2 to t3 and a time interval from t4 to t5. The controller dispenses the second treatment liquid at one time point in the time interval from t1 to t2, the time interval from t3 to t4, and the time interval from t5 to t6. The amount of the second treatment liquid dispensed is an amount by which the surface temperature of the substrate is lowered and remains constant.

According to an embodiment, in the substrate treating process, the second nozzle 391 may be fixed to dispense the second treatment liquid onto a set region of the substrate. The set region is a region, the temperature of which is measured to be high in a process of treating the first substrate. According to an embodiment, in the substrate treating process, the second nozzle 391 may dispense the second treatment liquid while moving above the set region of the substrate. The set region is a region, the temperature of which is measured to be high in the process of treating the first substrate.

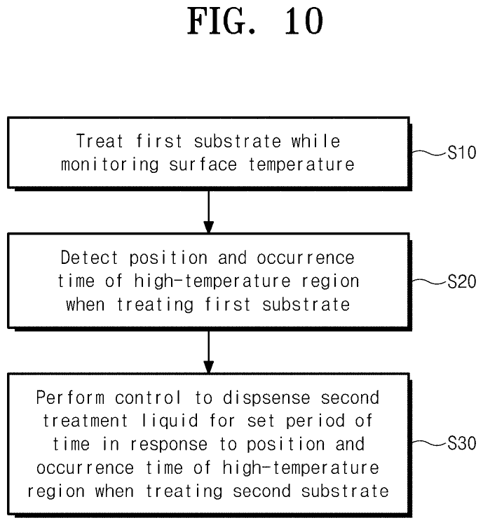

FIG. 10 is a flowchart illustrating a substrate treating method according to an embodiment. Referring to FIG. 10, the controller performs control to treat a first substrate while monitoring the surface temperature of the first substrate (S110). The controller receives an input of the position and the occurrence time of a high-temperature region at the time of treating the first substrate (S120). When treating a second substrate, the controller performs control to dispense the second treatment liquid in response to the input of the position and the occurrence time of the high-temperature region at the time of treating the first substrate (S130).

Although not illustrated, the third nozzle 381 may dispense the third treatment liquid in an oblique direction.

Although not illustrated, the length of the second arm 392 may be adjusted to be longer or shorter. Accordingly, the second nozzle 391 may be located over the entire area of the substrate.

According to the embodiments of the inventive concept, the etching rate and selectivity of a silicon nitride film may be improved by dispensing the first to third treatment liquids having different temperatures and concentrations onto a substrate for a set period of time in an overlapping manner.

According to the embodiments of the inventive concept, substrate temperature uniformity may be improved by dispensing the second treatment liquid based on the substrate surface temperature change measured for the first substrate.

According to the embodiments of the inventive concept, the substrate treating apparatus and method may efficiently treat a substrate.

In addition, according to the embodiments of the inventive concept, the substrate treating apparatus and method may improve temperature uniformity when treating a substrate.

Effects of the inventive concept are not limited to the above-described effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for treating a substrate, the apparatus comprising:
a support unit configured to support the substrate and provided so as to be rotatable;
a heater configured to heat the substrate;
a first nozzle configured to dispense a first treatment liquid onto the substrate in a substrate treating process, the first treatment liquid being one of a phosphoric acid solution or a mixture of a phosphoric acid solution and a silicon-based chemical; and
a second nozzle configured to dispense a second treatment liquid onto the substrate in the substrate treating process, the second treatment liquid being one of a phosphoric acid solution or a mixture of a phosphoric acid solution and a silicon-based chemical.

2. The apparatus of claim 1, further comprising:
a controller; and
a temperature sensor configured to measure temperatures of respective regions of the substrate,
wherein the controller controls at least one of a dispensing position, dispensing time, and a dispensing flow rate of at least one of the first nozzle and the second nozzle, based on a temperature measurement result of the temperature sensor.

3. The apparatus of claim 2, wherein a dispensing position of the second treatment liquid corresponds to a region, the temperature of which is measured to be high in a process of treating a first substrate.

4. The apparatus of claim 2, wherein dispensing time of the second treatment liquid ranges from any time point when temperature starts to rise in a process of treating a first substrate to any time point before the temperature falls.

5. The apparatus of claim 1, further comprising:
a controller,
wherein the controller performs control such that a state in which the second treatment liquid is dispensed for a set period of time and a state in which the second treatment liquid is not dispensed for the set period of time are repeated.

6. The apparatus of claim 1, wherein the second nozzle dispenses the second treatment liquid in a spray form.

7. The apparatus of claim 1, wherein the first treatment liquid is dispensed through the first nozzle at a temperature of 130 degrees Celsius to 200 degrees Celsius, and
wherein the second treatment liquid is dispensed through the second nozzle at a temperature of 130 degrees Celsius to 200 degrees Celsius.

8. The apparatus of claim 1, wherein the first treatment liquid is dispensed at a flow rate of 0 cc/min to 1000 ccc/min, and
wherein the second treatment liquid is dispensed at a flow rate of 0 cc/min to 1000 ccc/min.

9. The apparatus of claim 1, further comprising:
a third nozzle configured to dispense a third treatment liquid onto the substrate in the substrate treating process, the third treatment liquid being a silicon-based chemical.

10. The apparatus of claim 9, wherein the third treatment liquid additionally contains one of a phosphoric acid solution or DIW, in addition to the silicon-based chemical.

11. The apparatus of claim 10, wherein the concentration of silicon (Si) contained in the third treatment liquid is higher than the concentration of silicon (Si) contained in the first treatment liquid and the second treatment liquid.

12. The apparatus of claim 10, wherein the first treatment liquid is dispensed at a temperature of 130 degrees Celsius to 200 degrees Celsius, wherein the second treatment liquid is dispensed at a temperature of 130 degrees Celsius to 200 degrees Celsius, and
wherein the third treatment liquid is dispensed at a temperature of 10 degrees Celsius to 175 degrees Celsius.

13. The apparatus of claim 10, wherein the first treatment liquid is dispensed at a flow rate of 0 cc/min to 1000 ccc/min,
wherein the second treatment liquid is dispensed at a flow rate of 0 cc/min to 1000 ccc/min, and
wherein the third treatment liquid is dispensed at a flow rate of 0 cc/min to 100 ccc/min.

14. The apparatus of claim 10, wherein at least one of the first nozzle, the second nozzle, and the third nozzle dispenses a liquid while moving above a set region of the substrate.

15. The apparatus of claim 10, wherein the third nozzle dispenses the third treatment liquid while moving above a set region of the substrate in the substrate treating process.

16. The apparatus of claim 10, wherein the second nozzle is fixed to dispense the second treatment liquid onto a set region of the substrate in the substrate treating process.

17. The apparatus of claim 1, wherein the heater includes a heating member configured to heat the substrate by region.

18. An apparatus for treating a substrate, the apparatus comprising:
a support unit configured to support the substrate and provided so as to be rotatable;
a heater configured to heat the substrate;
a first nozzle configured to dispense a first treatment liquid onto the substrate in a substrate treating process, the first treatment liquid being one of a phosphoric acid solution or a mixture of a phosphoric acid solution and a silicon-based chemical;
a second nozzle configured to dispense a second treatment liquid onto the substrate in the substrate treating process, the second treatment liquid being one of a phosphoric acid solution or a mixture of a phosphoric acid solution and a silicon-based chemical;
a third nozzle configured to dispense a third treatment liquid onto the substrate in the substrate treating process, the third treatment liquid being a silicon-based chemical;
a temperature sensor configured to measure temperatures of respective regions of the substrate; and
a controller,
wherein the concentration of silicon (Si) contained in the third treatment liquid is higher than the concentration of silicon (Si) contained in the first treatment liquid and the second treatment liquid,
wherein the controller controls at least one of a dispensing position, dispensing time, and a dispensing flow rate of at least one of the first nozzle and the second nozzle, based on a temperature measurement result of the temperature sensor,
wherein a dispensing position of the second treatment liquid corresponds to a region, the temperature of which is measured to be high in a process of treating a first substrate, and
wherein dispensing time of the second treatment liquid ranges from any time point when temperature starts to rise in a process of treating the first substrate to any time point before the temperature falls.

19. The apparatus of claim 18, wherein the first treatment liquid is dispensed at a temperature of 130 degrees Celsius to 200 degrees Celsius,
wherein the second treatment liquid is dispensed at a temperature of 130 degrees Celsius to 200 degrees Celsius, and
wherein the third treatment liquid is dispensed at a temperature of 10 degrees Celsius to 175 degrees Celsius.

20. The apparatus of claim 19, wherein the first treatment liquid is dispensed at a flow rate of 0 cc/min to 1000 ccc/min,
wherein the second treatment liquid is dispensed at a flow rate of 0 cc/min to 1000 ccc/min, and
wherein the third treatment liquid is dispensed at a flow rate of 0 cc/min to 100 ccc/min.
